(19) United States
(12) Patent Application Publication
(10) Pub. No.: US 2024/0413109 A1
(43) Pub. Date: Dec. 12, 2024

(54) BONDING STRUCTURE FOR A HYBRID WAFER BONDING, SEMICONDUCTOR DEVICE INCLUDING THE BONDING STRUCTURE AND METHOD OF MANUFACTURING THE SEMICONDUCTOR DEVICE

(71) Applicant: SK hynix Inc., Icheon-si Gyeonggi-do (KR)

(72) Inventors: Young Su YUN, Icheon-si Gyeonggi-do (KR); Jung Hwan PARK, Icheon-si Gyeonggi-do (KR)

(73) Assignee: SK hynix Inc., Icheon-si Gyeonggi-do (KR)

(21) Appl. No.: 18/394,775

(22) Filed: Dec. 22, 2023

(30) Foreign Application Priority Data
Jun. 7, 2023 (KR) 10-2023-0073129

(51) Int. Cl. H01L 23/00

(52) U.S. Cl. CPC H01L 24/08; H01L 24/03; H01L 24/05; H01L 2224/03848; H01L 2224/05686; H01L 2224/08059; H01L 2224/08145; H01L 2924/351

(57) ABSTRACT

A bonding structure for a hybrid wafer bonding may include a plurality of bonding pads and a bonding insulation layer. The bonding insulation layer may be configured to electrically isolate the bonding pads from each other. The bonding insulation layer may include at least one dielectric layer and a vertical expansion inducing layer arranged on the dielectric layer. The vertical expansion inducing layer including a hardness greater than a hardness of the dielectric layer.

### CROSS-REFERENCES TO RELATED APPLICATION

The present application claims priority under 35 U.S.C. § 119 (a) to Korean application number 10-2023-0073129, filed on Jun. 7, 2023, in the Korean Intellectual Property Office, which is incorporated herein by reference in its entirety.

### BACKGROUND

### 1. Technical Field

Various embodiments generally relate to a bonding structure for a hybrid wafer bonding, a semiconductor device including the bonding structure and a method of manufacturing the semiconductor device.

### 2. Related Art

A hybrid wafer bonding may be a three-dimensional stacking technology that directly bonds two wafers with integrated circuits.

Each of the wafers to be bonded may include a plurality of metal pads and a dielectric layer at its bonding interface, respectively. The dielectric layers of the wafers may be directly contacted by bonding force. The metal pads of the wafers may be directly contacted by thermal expansion using an annealing process. In order to sufficiently thermally expand the metal pads, a material of the dielectric layer around the metal pads as well as an annealing temperature, a size of the metal pads, etc., may be important.

### SUMMARY

According to various embodiments, there may be provided a bonding structure for a hybrid wafer bonding. The bonding structure may comprise a plurality of bonding pads and a bonding insulation layer. The bonding insulation layer may be configured to electrically isolate the bonding pads from each other. The bonding insulation layer includes at least one dielectric layer and at least one vertical expansion inducing layer on the dielectric layer. The vertical expansion inducing layer includes a hardness greater than a hardness of the dielectric layer.

According to various embodiments, there may be provided a semiconductor device. The semiconductor device may comprise a first bonding structure including a first bonding layer and a second bonding structure including a second bonding layer bonded to the first bonding layer. At least one of the first bonding layer and the second bonding layer comprises a plurality of bonding pads and a bonding insulation layer. The bonding insulation layer is arranged between the bonding pads. The bonding insulation layer includes an upper region adjacent to a bonding surface between the first and second bonding layers and a lower region under the upper region.

According to various embodiments, there may be provided a semiconductor device. The semiconductor device may comprise a device layer and a bonding layer. The bonding layer is formed over the device layer. The bonding layer includes a bonding insulation layer and at least one bonding pad formed in the bonding insulation layer. The bonding insulation layer includes a plurality of dielectric layers stacked from the device layer toward a bonding surface. At least one of the dielectric layers adjacent to the bonding surface comprises a first dielectric material, and remaining dielectric layers comprise a second dielectric material including a hardness less than a hardness of the first dielectric material.

According to various embodiments, there may be provided a method of manufacturing a semiconductor device. In the method of manufacturing the semiconductor device, a first structure may be provided. The first structure may include a first bonding insulation layer and a plurality of first bonding pads. The first bonding insulation layer may include a first vertical expansion inducing layer. The first bonding pads may be formed in the first bonding insulation layer. A second structure may be provided. The second structure may include a second bonding insulation layer and a plurality of second bonding pads. The second bonding pads may be formed in the second bonding insulation layer. The first vertical expansion inducing layer of the first bonding insulation layer may be bonded to the second bonding insulation layer. The first bonding pad and the second bonding pad may be thermally expanded in a vertical direction by the first vertical expansion inducing layer to hybrid-bond the first bonding pad to the second bonding pad.

### BRIEF DESCRIPTION OF THE DRAWINGS

The above and another aspects, features and advantages of the subject matter of the present disclosure will be more clearly understood from the following detailed description taken in conjunction with the accompanying drawings, in which:

FIGS. 1A, 1B, and 1C are cross-sectional views illustrating a method of manufacturing a semiconductor device using a comparative example of a hybrid wafer bonding process;

FIG. 2A is a cross-sectional view illustrating bonding structures including a metal pad with a dishing according to an embodiment;

FIG. 2B is a cross-sectional view illustrating a semiconductor device with a disconnection according to an embodiment;

FIGS. 3A, 3B, 3C, and 3D are cross-sectional views illustrating various examples of first bonding structures in accordance with various embodiments;

FIG. 4 is a cross-sectional view illustrating a first bonding structure including a lower structure in accordance with various embodiments;

FIGS. 5A, 5B, 5C, and 5D are cross-sectional views illustrating various embodiments of a semiconductor device including a second bonding structure and a third bonding structure having different structures in accordance with various embodiments;

FIGS. 6A, 6B, 6C, and 6D are cross-sectional views illustrating various embodiments of a semiconductor device including a second bonding structure and a fourth bonding structure in accordance with various embodiments;

FIG. 7 is a flow chart for illustrating a method of manufacturing a semiconductor device in accordance with various embodiments;

FIGS. 8A, 8B, 8C, 8D, and 8E are cross-sectional views illustrating a method of manufacturing a semiconductor device in accordance with various embodiments;

FIGS. 9A, 9B, and 9C are cross-sectional views illustrating a hybrid bonding method of a lower bonding structure and an upper bonding structure according to an embodiment; and

FIG. 10 is a cross-sectional view illustrating a semiconductor memory device including hybrid bonded wafers in accordance with various embodiments.

### DETAILED DESCRIPTION

Various embodiments will be described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present application as defined in the appended claims. It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present. Like numerals refer to like elements throughout. It will be understood that although the terms first, second, third etc. may be used herein to describe various elements, these elements should not be limited by these terms. These terms are only used to distinguish one element from another element, but not used to define only the element itself or to mean a particular sequence. Spatially relative terms, such as “under,” “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “under” or “beneath” other elements or features would then be oriented “above” the other elements or features. Thus, the example of the term “below” can encompass both an orientation of above and below. The device may be otherwise oriented (rotated 90 degrees or at other orientations) and the spatially relative descriptors used herein interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent smaller than the extent of an underlying or overlying structure. Further, a layer can be a region of a homogeneous or inhomogeneous continuous structure that has a thickness less than the thickness of the continuous structure. For example, a layer can be located between any pair of horizontal planes or between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or via contacts are formed) and one or more dielectric layers.

As used herein, the term “about” indicates the value of a given quantity that can vary based on a particular technology node associated with the subject semiconductor device. Based on the particular technology node, the term “about” can indicate a value of a given quantity that varies within, for example, 10%˜30% of the value.

As used herein, a “wafer” is a piece of a semiconductor material for semiconductor devices to build in and/or on it and that can undergo various fabrication processes before being separated into dies.

Various embodiments in accordance with the present disclosure provide a semiconductor device which includes a bonding structure including a bonding insulation layer and at least one pad arranged in the bonding insulation layer. The bonding insulation layer may include a vertical expansion inducing layer as a part of a bonding insulation layer. The vertical expansion inducing layer may occupy about 40% to about 90% of the bonding insulation layer. The vertical expansion inducing layer may have relatively high strength and hardness compared to other materials constituting the bonding insulation layer. For example, the vertical expansion inducing layer may include at least one of nitrogen and carbon. The vertical expansion inducing layer may generate interface stress so that the bonding pad may thermally expand in the vertical direction.

Further, the vertical expansion inducing layer may be formed in at least one of an upper, middle or lower region of the bonding insulation layer.

Further, when the bonding structures having the vertical expansion inducing layers are hybrid-bonded, the bonding structures may be bonded so that the vertical expansion inducing layers are faced to each other.

According to various embodiments, there may be provided a bonding structure for a hybrid wafer bonding. The bonding structure may include a multi-layered dielectric layer and a metal pad. The multi-layered dielectric layer may include an oxide layer and a nitride layer. The metal pad may be arranged in the multi-layered dielectric layer. A volume ratio of the nitride layer with respect to a total volume of the multi-layered dielectric layer may be about 40% to about 90%.

According to various embodiments, there may be provided a semiconductor device. The semiconductor device may include a lower bonding structure and an upper bonding structure. The lower bonding structure may include a lower dielectric layer and a lower metal pad in the lower dielectric layer. The upper bonding structure may include an upper dielectric layer and an upper metal pad in the upper dielectric layer. The upper bonding structure may be bonded to the lower bonding structure with facing an upper surface of the lower metal pad to an upper surface of the upper metal pad. At least one of the lower dielectric layer and the upper dielectric layer may include a multi-layered dielectric layer. The multi-layered dielectric layer may include an oxide layer and a nitride layer. A volume ratio of the nitride layer with respect to a total volume of the multi-layered dielectric layer may be about 40% to about 90%.

In various embodiments, the multi-layered dielectric layer may include a silicon nitride layer (SiN), a silicon oxide layer (SiO₂) and a silicon carbon nitride layer (SiCN) sequentially stacked. A volume ratio of the silicon nitride layer and the silicon carbon nitride layer with respect to the total volume of the multi-layered dielectric layer may be about 50% to about 70%. A volume ratio of the silicon oxide layer with respect to the total volume of the multi-layered dielectric layer may be about 30% to about 50%.

According to various embodiments, there may be provided a method of manufacturing a semiconductor device. In the method of manufacturing the semiconductor device, a lower metal layer may be formed on a lower dielectric layer having a first opening. An upper metal layer may be formed on an upper dielectric layer having a second opening. The lower metal layer may be partially removed to form a lower bonding structure. The lower bonding structure may include an exposed lower metal pad and an exposed upper surface of the lower dielectric layer over the first opening. The upper metal layer may be partially removed to form an upper bonding structure. The upper bonding structure may include an exposed upper metal pad and an exposed upper surface of the upper dielectric layer over the second opening. The upper bonding structure may be bonded to the lower bonding structure with facing an upper surface of the lower metal pad to an upper surface of the upper metal pad with each other. The lower dielectric layer may be bonded to the upper dielectric layer to form a bonding stacking structure. The bonding stacking structure may be heated to bond the lower metal pad to the upper metal pad. At least one of the lower dielectric layer and the upper dielectric layer may include a multi-layered dielectric layer. The multi-layered dielectric layer may include an oxide layer and a nitride layer. A volume ratio of the nitride layer with respect to a total volume of the multi-layered dielectric layer may be about 40% to about 90%.

According to various embodiments, there may be provided a bonding structure for a hybrid wafer bonding. The bonding structure may include a plurality of bonding pads and a bonding insulation layer. The bonding insulation layer may be configured to electrically isolate the bonding pads from each other. The bonding insulation layer may include at least one dielectric layer and a vertical expansion inducing layer arranged on the dielectric layer. The vertical expansion inducing layer may have a hardness higher than a hardness of the dielectric layer.

According to various embodiments, there may be provided a semiconductor device. The semiconductor device may include a first structure and a second structure. The first structure may include a first bonding layer. The second structure may include a second bonding layer boned to the first bonding layer. At least one of the first bonding layer and the second bonding layer may include a plurality of bonding pads and a bonding insulation layer interposed between the bonding pads. The bonding insulation layer may include an upper region adjacent to a bonding surface between the first and second bonding layers and a lower region positioned under the upper region. An interface stress between the upper region and the bonding pad in the bonding insulation layer may be higher than an interface stress between the lower region and the bonding pad in the bonding insulation layer.

According to various embodiments, there may be provided a semiconductor device. The semiconductor device may include a device layer, a bonding insulation layer and a bonding layer. The bonding insulation layer may be formed on at least one of surfaces of the device layer. The bonding insulation layer may include a plurality of dielectric layers stacked from the surface of the device layer to a bonding surface. The bonding layer may include a plurality of bonding pads interposed between a plurality of the bonding insulation layers. At least one of the dielectric layers adjacent to the bonding surface may include a first dielectric material. Remaining dielectric layers may include a second dielectric material having a hardness lower than a hardness of the first dielectric material.

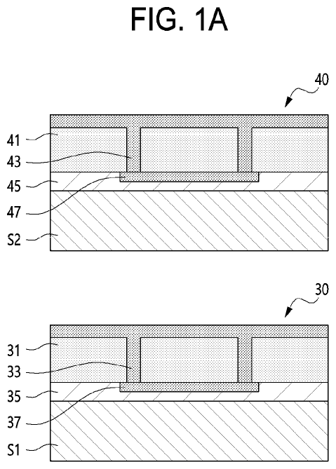

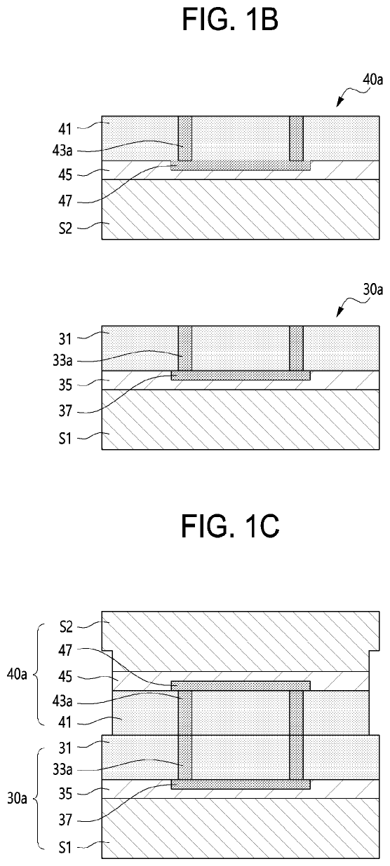

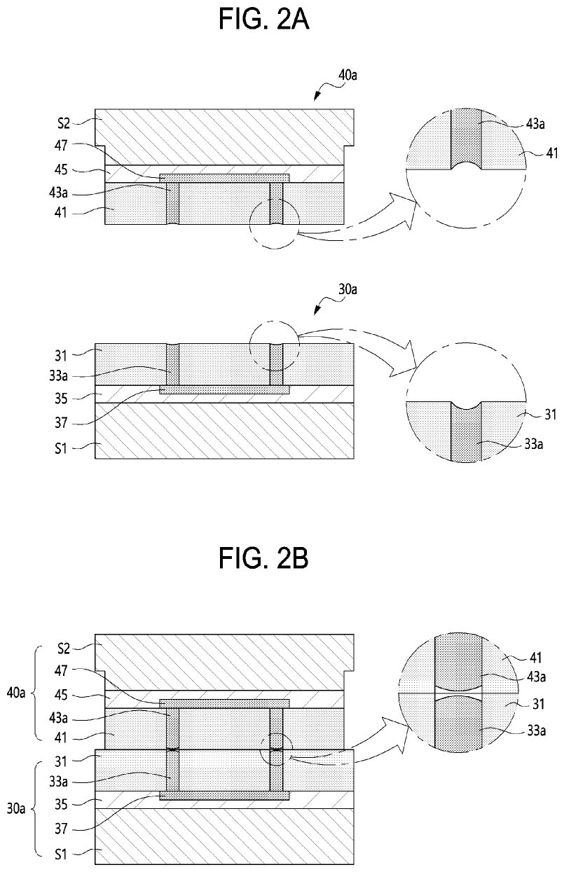

FIGS. 1A to 1C are cross-sectional views illustrating a method of manufacturing a semiconductor device using a comparative example of a hybrid wafer bonding process. FIG. 2A is a cross-sectional view illustrating bonding structures including metal pads with a dishing according to an embodiment and FIG. 2B is a cross-sectional view illustrating a semiconductor device with a disconnection according to an embodiment.

Referring to FIG. 1A, in a comparative example of a hybrid wafer bonding process, a first stacking structure 30 and a second stacking structure 40 may be prepared.

The first stacking structure 30 may include an upper dielectric layer 31 as a bonding insulating layer and a metal layer 33 in the upper dielectric layer 31. For example, the upper dielectric layer 31 and the metal layer 33 may be formed over a first substrate S1. The first stacking structure 30 may further include at least one interlayer insulation film 35 and at least one conductive pattern 37 in the interlayer insulation film 35. For example, the metal layer 33 may be electrically connected to the conductive pattern 37.

The first stacking structure 30 may be formed by the following processes.

The interlayer insulation film 35 may be formed over the first substrate S1. The interlayer insulation film 35 may be etched. The conductive pattern 37 may then be formed in a portion where the interlayer insulation film 35 is etched. The upper dielectric layer 31 may be formed over the interlayer insulation film 35. The upper dielectric layer 31 may be etched to form at least one opening. A metal material may be formed on the upper dielectric layer 31 to fill the opening, to form the metal layer 33.

The second stacking structure 40 may include an upper dielectric layer 41 as a bonding insulating layer, a metal layer 43, at least one interlayer insulation film 45 and at least one conductive pattern 47. The upper dielectric layer 41 may be formed on a second substrate S2. The conductive pattern 47 may be electrically connected with the metal layer 43. For example, the second stacking structure 40 may be formed by processes substantially the same as the processes for forming the first stacking structure 30.

Referring to FIG. 1B, each of the metal layers 33 and 43 of FIG. 1A may be polished by a chemical mechanical polishing (CMP) process until the upper dielectric layers 31 and 41 are exposed to form a first bonding structure 30a with first metal pads 33a and a second bonding structure 40a with second metal pads 43a. Here, the first metal pads 33a and the second metal pads 43a may correspond to bonding pads. Here, the first and second metal pads 33a and 43a may be understood as bonding pads of each of the first and second bonding structures 30a and 40a. Further, the upper dielectric layers 31 and 41 may be understood as a bonding insulating layer of each of the first and second bonding structures 30a and 40a.

Referring to FIG. 1C, the second bonding structure 40a may be arranged over the first bonding structure 30a to face the first and second metal pads 33a and 43a to each other. The upper dielectric layer 31 and 41 may be bonded to each other. The bonded upper dielectric layers 31 and 41 may be annealed to bond the first and second metal pads 33a and 43a, thereby forming a semiconductor device including the first and second bonding structures 30a and 40a which are hybrid bonded.

However, when each of the metal layers 33 and 43 are polished by the CMP process, each of the metal layers 33 and 43 may be partially over-polished due to a material property difference between the upper dielectric layers 31 and 41 and the metal layers 33 and 43. Thus, as shown in FIG. 2A, a dishing occurs at the upper surfaces of the first and second metal pads 33a and 43a.

Referring to FIG. 2B, the first and second metal pads 33a and 43a with the dishing might not be sufficiently expanded in the annealing process. When the first and second metal pads 33a and 43a might not be sufficiently expanded, a productivity of the semiconductor device may be decreased due to a disconnection generated at the first and second metal pads 33a and 43a.

Particularly, the bonding first and second structures 30a and 40a should be electrically connected with each other by the hybrid wafer bonding process. In the hybrid bonding process, the upper dielectric layer 31 and the upper dielectric layer 41 may be directly bonded to each other. The bonding between the upper dielectric layers 31 and 41 may be induced by a heating at a room temperature or a low temperature. Meanwhile, the first and second metal pads 33a and 43a might not bond under a bonding condition of the upper dielectric layers 31 and 41. Thus, interfaces between the first and second metal pads 33a and 43a might not be electrically connected with each other. The first and second metal pads 33a and 43a may be annealed at a temperature of about 100° C. to about 300° C. to bond the first and second metal pads 33a and 43a to each other.

The heated first and second metal pads 33a and 43a may be upwardly expanded by the annealing process so that the first and second metal pads 33a and 43a may make contact with each other. A sufficient stress may be applied to the first and second metal pads 33a and 43a to bond the first and second metal pads 33a and 43a to each other. After cooling the bonded first and second metal pads 33a and 43a, the first and second metal pads 33a and 43a might not be separated from each other. Thus, an electrical bonding between the first and second metal pads 33a and 43a may be maintained. The first and second metal pads 33a and 43a may have a thermal expansion coefficient higher than a thermal expansion coefficient of the upper dielectric layers 31 and 41. Thus, in an embodiment, when the first and second bonding structures 30a and 40a may be heated by the annealing process, the upper dielectric layers 31 and 41 at sides of the first and second metal pads 33a and 43a may prevent or mitigate thermal expansions of the first and second metal pads 33a and 43a along lateral directions to generate an interface stresses, thereby applying the interface stress to the first and second metal pads 33a and 43a.

If the first and second metal pads 33a and 43a are insufficiently thermally expanded, the first and second metal pads 33a and 43a may be disconnected. Particularly, when the dishing may be generated at the first and second metal pads 33a and 43a, although the first and second metal pads 33a and 43a may be sufficiently heated by the annealing process, the first and second metal pads 33a and 43a may be disconnected. A deformation amount of the thermal expansion in the first and second metal pads 33a and 43a by the annealing process may be affected by Young's modulus of the upper dielectric layers 31 and 41 adjacent to the first and second metal pads 33a and 43a. Particularly, when the first and second metal pads 33a and 43a may be thermally expanded, the thermal expansions of the first and second metal pads 33a and 43a may be induced by the hard upper dielectric layers 31 and 41. Therefore, for some embodiments, bonding structures 100a, 100b, 100c and 100d for a hybrid wafer bonding in accordance with various embodiments may include a dielectric layer around a metal pad.

In an embodiment, a dielectric layer as the bonding insulation layer may include a dielectric material having a higher strength and a higher hardness than those of silicon oxide layer commonly used as the bonding insulation layer. The dielectric material may apply sufficient stress to the metal pad based on a material difference between the dielectric material and the metal pad, when the metal pad is annealed. Thus, the metal pad may thermally expand toward a bonding surface, for example, a vertical direction, based on the sufficient stress.

Hereinafter, the bonding structures for a hybrid wafer bonding in accordance with various embodiments (hereinafter, referred to as first bonding structures) may be illustrated in detail.

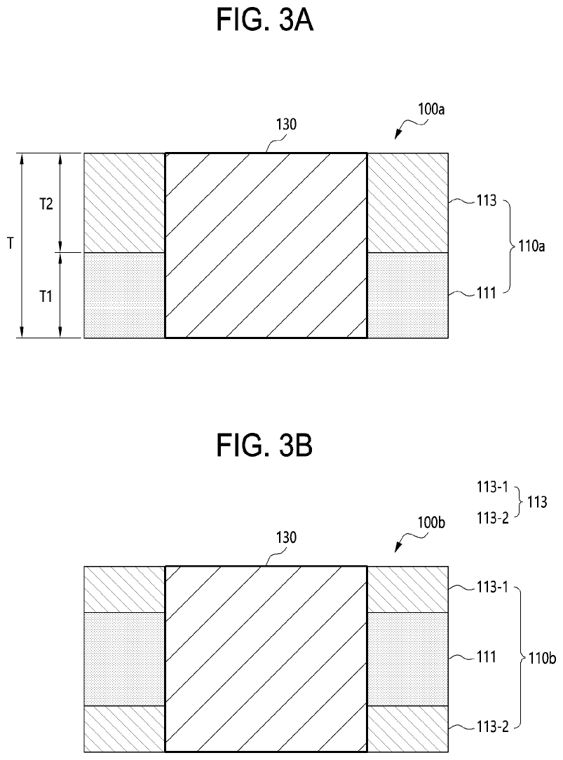

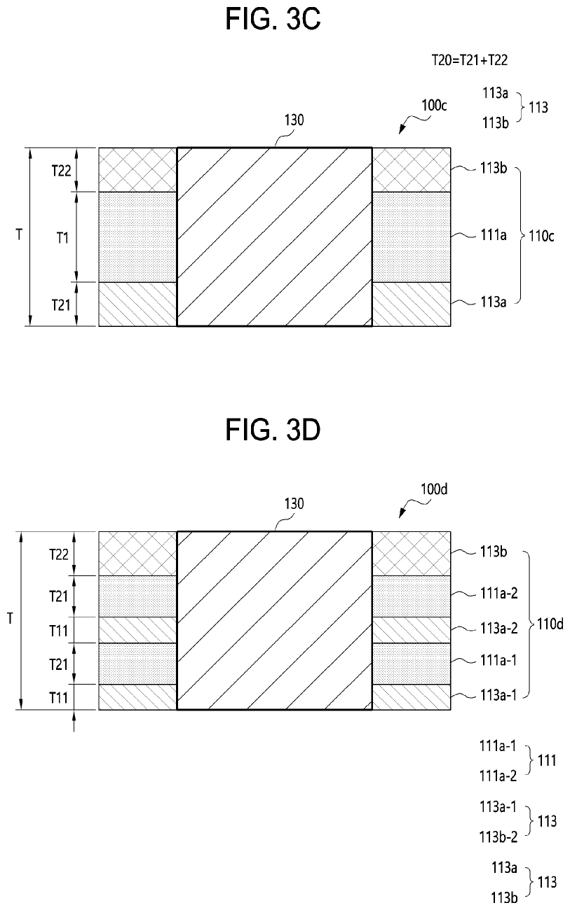

FIGS. 3A to 3D are cross-sectional views illustrating various examples of first bonding structures in accordance with various embodiments.

Referring to FIGS. 3A to 3D, the first bonding structures 100a, 100b, 100c and 100d may include a first multi-layered dielectric layer 110a, 110b, 110c and 110d and a first metal pad 130. Thus, the first bonding structures 100a, 100b, 100c and 100d may be bonded to each other at interfaces between the first bonding structures 100a, 100b, 100c and 100d without a disconnection in the hybrid-bonding process.

The first metal pad 130 may be formed in at least one of the first multi-layered dielectric layer 110a, 110b, 110c and 110d. The first metal pad 130 may include a material thermally expanded by an annealing process at a high temperature above 250° C. For example, the first metal pad 130 may include copper, aluminum, tungsten, a combination thereof, etc. In various embodiments, the first metal pad 130 may include copper.

At least one of the first multi-layered dielectric layer 110a, 110b, 110c and 110d may include at least one oxide layer and at least one nitride layer.

For example, the first multi-layered dielectric layer 110a, 110b, 110c and 110d may correspond to the bonding insulation layer.

To explain in more detail, referring to FIG. 3A, the first bonding structure 100a may include the first multi-layered dielectric layer 110a and the first metal pad 130 in the first multi-layered dielectric layer 110a.

For example, the first multi-layered dielectric layer 110a may include a first oxide layer 111 and a first nitride layer 113.

In an embodiment, the first oxide layer 111 may buffer a stress generated from the first metal pad 130. Further, the first oxide layer 111 may prevent or mitigate a stress of the first metal pad 130 during the annealing process.

In embodiments, the first nitride layer 113 may include a dielectric material with a modulus higher than a modulus of the first oxide layer 111. In other words, the nitride material may include higher strength and higher hardness than those of oxide material. Thus, in an embodiment, the first nitride layer 113 may prevent or mitigate a thermal expansion of the first metal pad 130 in a lateral direction (or a horizontal direction), during the annealing process. Further, the first nitride layer 113 may induce the thermal expansion of the first metal pad 130 along a vertical direction perpendicular to the lateral direction.

The first nitride layer 113 may occupy 40% to 90% of the first multi-layered dielectric layer 110a. For example, a volume ratio of the first nitride layer 113 with respect to a total volume of the first multi-layered dielectric layer 110a may be about 40% to about 90%. Further, a volume ratio of the first oxide layer 111 with respect to the total volume of the first multi-layered dielectric layer 110a may be about 10% to about 60%. In this embodiment, “volume” may be interpreted as a term including thickness.

When the volume ratio of the first nitride layer 113 with respect to the total volume of the first multi-layered dielectric layer 110 may be below about 40%, the first metal pad 130 might not be sufficiently thermally expanded in the vertical direction to generate the disconnection. In contrast, when the volume ratio of the first nitride layer 113 with respect to the total volume of the first multi-layered dielectric layer 110 may be above about 90%, the first metal pads 130 may be excessively thermally expanded in the vertical direction, so that the first metal pad 130 is expanded into an abnormal shape in the first multi-layered dielectric layer 110. Particularly, the volume ratio of the first nitride layer 113 with respect to the total volume of the first multi-layered dielectric layer 110 may be about 40% to about 90%, more particularly, about 50% to about 60%.

The first nitride layer 113 may be formed on the first oxide layer 111. Alternatively, the first oxide layer 111 may be formed on the first nitride layer 113. The positions of the first oxide layer 111 and the first nitride layer 113 in the first multi-layered dielectric layer 110a may be changed in accordance with designs of the semiconductor device.

The first oxide layer 111 may include silicon oxide (SiO₂). The first nitride layer 113 may include at least one nitride and carbon. For example, the first nitride layer 113 may include at least one of silicon nitride (SiN), silicon carbon nitride (SiCN) and silicon oxynitride (SiON). Hereinafter, the oxide layer 111 will be understood as the silicon oxide layer.

As shown in FIG. 3A, the first multi-layered dielectric layer 110a may include the single first oxide layer 111 and the single first nitride layer 113, but not limited thereto.

Referring to FIG. 3B, the first multi-layered dielectric layer 110b of the first bonding structure 100b may include a first nitride layer 113-1, a first oxide layer 111 and a second nitride layer 113-2 which are sequentially stacked. A volume ratio of the first and second nitride layers 113-1 and 113-2 with respect to the total volume of the first multi-layered dielectric layer 110b may be about 40% to about 90%. A volume ratio of the first oxide layer 111 with respect to the total volume of the first multi-layered dielectric layer 110b may be about 10% to about 60%.

The first nitride layer 113-1 and the second nitride layer 113-2 may include nitride having a same composition or different compositions. The first nitride layer 113-1 and the second nitride layer 113-2 may have a same volume ratio or different volume ratios. That is, the first nitride layer 113-1 and the second nitride layer 113-2 may have the same thickness or different thicknesses.

Alternately, the first oxide layer 111 and the nitride layers 113 may be alternately stacked at least once, to form a first multi-layered dielectric layer 110a or 110b as a bonding insulation layer.

Referring to FIG. 3C, the first multi-layered dielectric layer 110c of the first bonding structure 100c may include a first silicon nitride layer 113a, a first silicon oxide layer 111a and a first silicon carbon nitride layer 113b sequentially stacked. For example, the first silicon carbon nitride layer 113b may have a greater strength and hardness than those of the first silicon oxide layer 111a.

In an embodiment, the first silicon nitride layer 113a and the first silicon carbon nitride layer 113b may correspond to a vertical expansion inducing layer of the first multi-layered dielectric layer 110c.

A volume ratio of the first silicon nitride layer 113a and the first silicon carbon nitride layer 113b with respect to the total volume of the first multi-layered dielectric layer 110c may be about 40% to about 90%, particularly, about 50% to about 70%. A volume ratio of the first silicon oxide layer 111a with respect to the total volume of the first multi-layered dielectric layer 110c may be about 10% to about 60%. The first silicon nitride layer 113a and the first silicon carbon nitride layer 113b in the first multi-layered dielectric layer 110c may be within a category of the nitride layer 113. The first silicon oxide layer 111a may be within a category of the oxide layer 111.

Referring to FIG. 3D, the first multi-layered dielectric layer 110d of the first bonding structure 100d may include a plurality of silicon nitride layer and a plurality of silicon oxide layer which are alternately stacked. For example, the nitride layer may be located in uppermost and lowermost layers of the first multi-layered dielectric layer 110d. For example, the nitride layer may include at least one of the silicon nitride layer and the silicon carbon nitride layer. In an embodiment, the first multi-layered dielectric layer 110d may include a first silicon nitride layer 113a-1, a first silicon oxide layer 111a-1, a second silicon nitride layer 113a-2, a second silicon oxide layer 111a-2 and a first silicon carbon nitride layer 113b which are sequentially stacked.

Alternately, the first silicon nitride layer 113a-1 and the first silicon oxide layer 111a-1 may be alternately stacked at least twice, to form the first multi-layered dielectric layer 110d. The first silicon carbon nitride layer 113b may be stacked on an uppermost layer in the first bonding structure 100d.

A volume ratio of the first silicon nitride layers 113a-1 and 113a-2 and the first silicon carbon nitride layer 113b with respect to a total volume of the first multi-layered dielectric layer 110d may be about 40% to about 90%, particularly, about 50% to about 70%, more particularly, about 50% to about 60%. A volume ratio of the first and second silicon oxide layers 111a-1 and 111a-2 with respect to the total volume of the first multi-layered dielectric layer 110d may be about 10% to about 60%. The first silicon nitride layer 113a-1 and the first silicon carbon nitride layer 113b in the first multi-layered dielectric layer 110d may be within a category of the nitride layer. The first silicon oxide layer 111a-1 may be within a category of the oxide layer.

In an embodiment, in the first bonding structures 100a, 100b, 100c and 100d, the first nitride layer(s) 113 may have a modulus greater than a modulus of the first oxide layer(s) 111 to prevent or mitigate the thermal expansion of the metal pad 130 along the lateral direction in the annealing process so that the metal pad 130 may be sufficiently thermally expanded in the vertical direction to facilitate the bonding of the first metal pad 130 in the hybrid bonding process. The volume ratio of the nitride layer 113 with respect to the total volume of the dielectric layer may be about 40% to about 90%. The nitride layer 113 may include silicon nitride. Alternatively, the nitride layer 113 may include silicon nitride and silicon carbon nitride. The oxide layer 111 may include silicon oxide.

The first silicon carbon nitride layer 113b may have a density and a modulus greater than a density and a modulus of the silicon oxide layer 111 to improve the thermal expansion of the first metal pad 130. Further, in an embodiment, the silicon carbon nitride layer 113b may have good thermal stability, high bonding strength and a metal diffusion barrier characteristic so that the first silicon carbon nitride layer 113b may be used for a material for directly bonding the dielectric layers to each other. Thus, the silicon carbon nitride layer 113b may be the uppermost layer of the first bonding structures 100c and 100d.

In an embodiment, although the oxide layer 111 has a lower strength and a lower hardness than those of the nitride layer 113, the oxide layer 111 can define a space in which the metal pad 130 will be formed. Further, the oxide layer 111 may mitigate and buffer the stress among the metal pad 130, the silicon nitride layer 113a and the silicon carbon nitride layer 113b when the metal pad 130 is annealed.

The first bonding structures 100a, 100b, 100c and 100d may form the structure configured to bond the metal pads to each other at the interface without the disconnection in the hybrid wafer bonding process.

The volume ratio(s) may be adjusted by changing the thicknesses of the first oxide layer 111 and the first nitride layer 113.

For example, referring to FIG. 3A, when a thickness T of the first multi-layered structure 110a corresponding to the bonding insulating layer may be about 2,250 Å, a thickness T2 of the first nitride layer 113 may be about 900 Å to about 2,025 Å and a thickness T1 of the first oxide layer 111 may be about 225 Å to about 1,350 Å. Thus, the volume ratio of the nitride layer 113 with respect to the total volume of the first multi-layered structure 110a may be about 40% to about 90%. The volume ratio of the first oxide layer 111 with respect to the total volume of the first multi-layered structure 110a may be about 10% to about 60%. In various embodiments, the volume may be understood a thickness or a content.

In other words, referring to FIG. 3C, when the thickness T of the first multi-layered structure 110c may be about 2,250 Å, a total thickness T20 of a thickness T21 of the first silicon nitride layer 113a and a thickness T22 of the first silicon carbon nitride layer 113b may be about 900 Å to about 2,025 Å and the thickness T1 of the first oxide layer 111a may be about 225 Å to about 1,350 Å.

Referring to FIG. 3D, when the thickness T of the first multi-layered structure 110d may be about 2,250 Å, a total thickness T20 of the thicknesses T21 of the first silicon nitride layers 113a-1 and 113a-2 and the thickness T22 of the first silicon carbon nitride layer 113b may be about 900 Å to about 2,025 Å and thicknesses T11 of the first oxide layers 111a-1 and 111a-2 may be about 225 Å to about 1,350 Å.

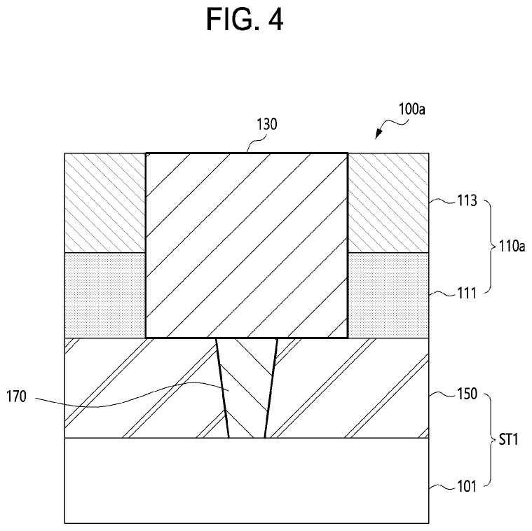

FIG. 4 is a cross-sectional view illustrating a first bonding structure including a lower structure in accordance with various embodiments.

Referring to FIG. 4, the first bonding structure 100a may include the first multi-layered dielectric layer 110a, the first metal pad 130 and a lower structure ST1. The first multi-layered dielectric layer 110a may be formed on the lower structure ST1. The lower structure ST1 may include a substrate 101, at least one insulation layer 150 and at least one conductive pattern 170. The insulation layer 150 may be interposed between the first multi-layered dielectric layer 110a and the substrate 101. The conductive pattern 170 may be formed in the insulation layer 150. For example, the conductive pattern 170 may be electrically connected to the first metal pad 130. In an embodiment, the substrate 101 may be removed.

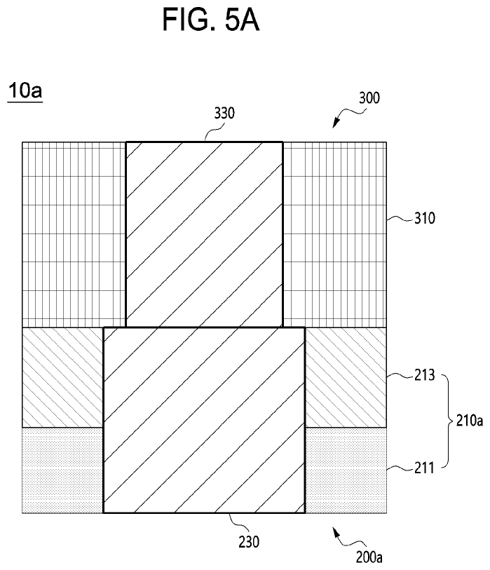

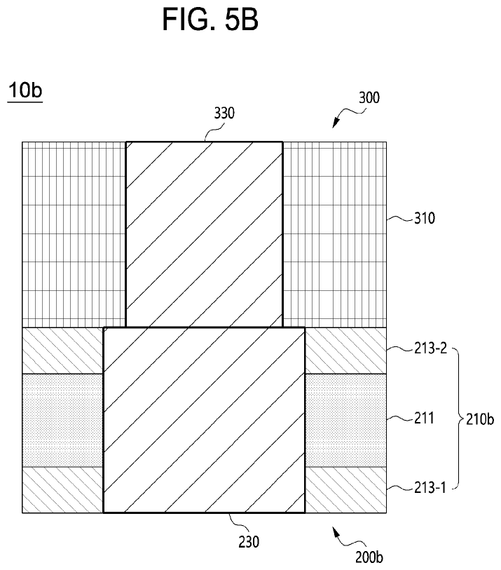

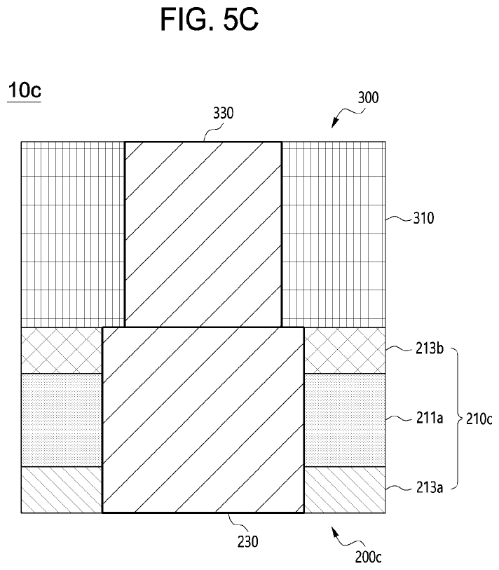

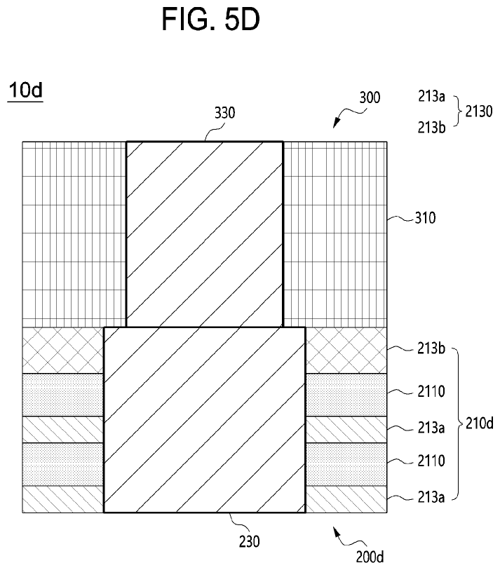

FIGS. 5A to 5D are cross-sectional views illustrating various examples of a semiconductor device including a second bonding structure and a third bonding structure having different structures in accordance with various embodiments.

Referring to FIGS. 5A to 5D, semiconductor devices 10a, 10b, 10c and 10d may include a second bonding structure 200a, 200b, 200c or 200d and a third bonding structure 300.

Any one of the second bonding structure 200a, 200b, 200c or 200d and the third bonding structure 300 may have a structure which is substantially the same as the structure of the first bonding structures 100a, 100b, 100c and 100d, which are shown in FIGS. 3A to 3D.

In the semiconductor devices 10a, 10b, 10c and 10d, the second bonding structure 200a, 200b, 200c or 200d may include a second multi-layered dielectric layer 210a, 210b, 210c or 210d and a second metal pad 230. The second metal pad 230 may be formed in the second multi-layered dielectric layer 210a, 210b, 210c or 210d. For example, the second multi-layered dielectric layer 210a, 210b, 210c or 210d may correspond to a bonding insulation layer of the second bonding structure 200a, 200b, 200c or 200d. The third bonding structure 300 may include a third dielectric layer 310 and a third metal pad 330. The third metal pad 330 may be formed in the third dielectric layer 310. The third dielectric layer may be a bonding insulation layer of the third bonding structure 300. The second bonding structure 200 and the third bonding structure 300 may have different structures. The second bonding structure 200 and the third bonding structure 300 may be hybrid-bonded to contact the second multi-layered dielectric layer 210a, 210b, 210c or 210d, and the third dielectric layer 310.

Referring to FIG. 5A, the second multi-layered dielectric layer 210a of the semiconductor device 10a may include at least one oxide layer 211 and at least one nitride layer 213. Since a strength and a hardness of the nitride layer 213 higher than those of the oxide layer 211, the nitride layer 213 may apply greater stress to the second metal pad 230 than the oxide layer 211. Thus, the nitride layer 213 may induce a thermal expansion of the second metal pad 230 toward to the third metal pad 330 (e.g. the vertical direction). For example, the oxide layer 211 may be positioned in a lower region of the second multi-layered dielectric layer 210a. The nitride layer 213 may be positioned in an upper region of the second multi-layered dielectric layer 210a. An upper surface of the nitride layer 213 may be a bonding surface bonded to the third bonding structure 300. An interface stress between the nitride layer 213 positioned in the upper region of the second multi-layered dielectric layer 210a and the second metal pad 230 corresponding to a bonding pad may be greater than an interface stress between the oxide layer 211 positioned in the lower region of the second multi-layered dielectric layer 210a and the second metal pad 230. For reference, a portion of each of multi-layered dielectric layers adjacent to the bonding surface will be referred to as the upper region and a portion of each of the multi-layered dielectric layers spaced apart from the bonding surface will be referred to as the low region. A middle region of the multi-layered dielectric layer may be positioned between the lower region and the upper region.

A volume ratio of the nitride layer 213 with respect to a total volume of the second multi-layered dielectric layer 210a may be about 40% to about 90%, particularly, 50% to about 70%, more particularly, 50% to about 60%. A volume ratio of the oxide layer 211 with respect to the total volume of the second multi-layered dielectric layer 210a may be about 10% to about 60%. For example, a thickness of the upper region including the nitride layer 213 is greater than a thickness of the lower region including the oxide layer 211.

Referring to FIG. 5B, the second multi-layered dielectric layer 210b of the semiconductor device 10b may include a first nitride layer 213-1, an oxide layer 211 and a second nitride layer 213-2. Here, the first nitride layer 213-1 and the second nitride layer 213-2 may be a vertical expansion inducing layer for inducing the thermal expansion of the second metal pad 230 toward the vertical direction. A volume ratio of the first and second nitride layers 213-1 and 213-2 with respect to a total volume of the second multi-layered dielectric layer 210b may be about 40% to about 90%, particularly, about 50% to about 70%, more particularly, about 50% to about 60%. A volume ratio of the oxide layer 211 with respect to the total volume of the second multi-layered dielectric layer 210b may be about 10% to about 60%.

For example, a volume ratio of the first nitride layer 213-1 and the second nitride layer 213-2 may be about 0.5:1.5 to about 1.5:0.5. The volume ratio may be formed by controlling thicknesses of the first nitride layer 213-1 and the second nitride layer 213-2. For example, when a thickness of the first nitride layer 213-1 may be about 1,500 Å to about 500 Å, the second nitride layer 213-2 may have a thickness of about 500 Å to about 1,500 Å. For example, the second multi-layered dielectric layer 210b of the semiconductor device 10b may include a first oxide layer, a first nitride layer, and a second oxide layer which are sequentially stacked. That is, the second oxide layer may be directly bonded to the third dielectric layer 310. Here, a volume ratio of the nitride layer with respect to the total volume of the second multi-layered dielectric layer 210b may be about 40% to about 90%, particularly, about 50% to about 70%, more particularly, about 50% to about 60%.

Referring to FIG. 5C, the second multi-layered dielectric layer 210c of the semiconductor device 10c may include a silicon nitride layer 213a, a silicon oxide layer 211a and a silicon carbon nitride layer 213b sequentially stacked. For example, the silicon nitride layer 213a may be positioned in a lower region of the second multi-layered dielectric layer 210c. The silicon oxide layer 211a may be positioned in a middle region of the second multi-layered dielectric layer 210c and the silicon carbon nitride layer 213b may be positioned in an upper region of the second multi-layered dielectric layer 210c. In this embodiment, the silicon nitride layer 213a and the silicon carbon nitride layer 213b may be a vertical expansion inducing layer for inducing the thermal expansion of the second metal pad 230 toward the vertical direction. A volume ratio of the silicon nitride layer 213a and the silicon carbon nitride layer 213b with respect to a total volume of the second multi-layered dielectric layer 210c may be about 40% to about 90%, particularly, about 50% to about 70%, more particularly, 50% to about 60%. A volume ratio of the oxide layer 211a with respect to the total volume of the second multi-layered dielectric layer 210c may be about 10% to about 60%.

Further, a volume ratio of the silicon nitride layer 213a and the silicon carbon nitride layer 213b may be about 0.5:1.5 to about 1.5:0.5. The volume ratio may be controlled by thicknesses of the silicon nitride layer 213a and the silicon carbon nitride layer 213b. For example, when a thickness of the silicon nitride layer 213a may be about 1,500 Å to about 500 Å, the silicon carbon nitride layer 213b may have a thickness of about 500 Å to about 1,500 Å.

For example, when the second multi-layered dielectric layer 210c has a thickness of about 2,200 Å, an aggregate thickness of the silicon nitride layer 213a and the silicon carbon nitride layer 213b may have a thickness of about 880 Å to about 1,980 Å to provide the volume ratio of the nitride layers 213a and 213b with about 40% to about 90% and the volume ratio of the oxide layer 211 with about 10% to about 60%.

Referring to FIG. 5D, the second multi-layered dielectric layer 210d of the semiconductor device 10d may include a vertical expansion inducing layer 2130 and a buffer layer 2110 alternately stacked. For example, the vertical expansion inducing layers 2130 may be located at a lower region and an upper region of the second multi-layered dielectric layer 210d. The vertical expansion inducing layer 2130 may include at least one of the silicon nitride layer 213a and the silicon carbon nitride layer 213b. For example, the silicon nitride layer 213a may be positioned in the lower region (e.g., a lowermost layer) of the second multi-layered dielectric layer 210d and the silicon carbon nitride layer 213b may be positioned in the upper region (e.g., an uppermost layer) of the second multi-layered dielectric layer 210d to be contacted to the third bonding structure 300. Thus, the silicon nitride layer 213a and the silicon carbon nitride layer 213b may induce a thermal expansion of the second metal pad 230 to the vertical direction. Here. the buffer layer 2110 may include a silicon oxide layer to mitigate the stress of the metal pad 230. In some embodiments, a silicon oxide layer (not shown) may be positioned at the uppermost surfaces of the second multi-layered dielectric layer 210a, 210b, 210c or 210d that is hybrid-bonded to the third dielectric layer 310.

A volume ratio of the vertical expansion inducing layer 2130 including the silicon nitride layers 213a and the silicon carbon nitride layer 213b with respect to a total volume of the second multi-layered dielectric layer 210d may be about 40% to about 90%, particularly, about 50% to about 70%, more particularly, about 50% to about 60%. A volume ratio of the buffer layer(s) 2110 with respect to the total volume of the second multi-layered dielectric layer 210d may be about 10% to about 60%.

Further, a volume ratio of the silicon nitride layers 213a and a volume ratio of the silicon carbon nitride layers 213b may be about 0.5:1.5 to about 1.5:0.5.

Referring to FIGS. 5A to 5D, the third bonding structure 300 of the semiconductor devices 10a, 10b, 10c and 10d may include a third dielectric layer 310 and a third metal pad 330 arranged in the third dielectric layer 310.

The third dielectric layer 310 may include a dielectric material bonded to the second multi-layered dielectric layers 210a, 210b, 210c and 210d. The dielectric material of the third dielectric layer 310 may include at least one of silicon oxide, silicon nitride, silicon carbon nitride, silicon oxynitride and silicon carbon oxynitride.

The third metal pad 330 may be formed in the third dielectric layer 310 and bonded to the second metal pad 230.

Accordingly, FIG. 5A to FIG. 5D may show the second bonding structure 200a, 200b, 200c, and 200d positioned under the third structure 300. Alternatively, the position of the second bonding structure 200 and the third bonding structure 300 may be reversed.

Further, in FIGS. 5A to 5D, the second metal pad 230 and the third metal pad 330 may have different cross-sectional shapes, but not limited thereto. For example, the second metal pad 230 and the third metal pad 330 may have a same cross-sectional shape. Particularly, the different cross-sectional shapes may be provided to the second metal pad 230 and the third metal pad 330 to secure a bonding margin between the second metal pad 230 and the third metal pad 330.

In an embodiment, the semiconductor devices 10a, 10b, 10c and 10d may form the bonded structure at the interfaces by the hybrid bonding process without the disconnection.

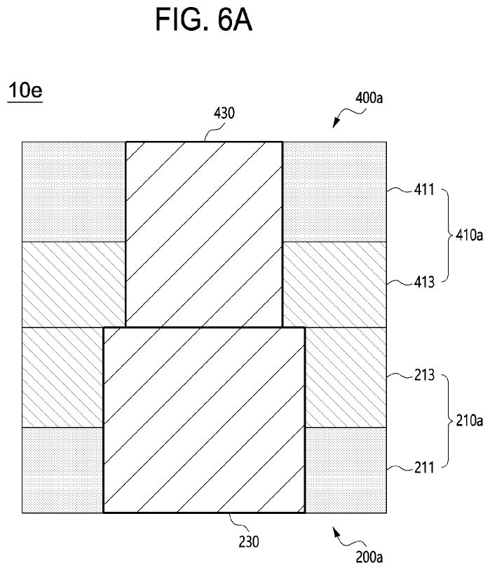

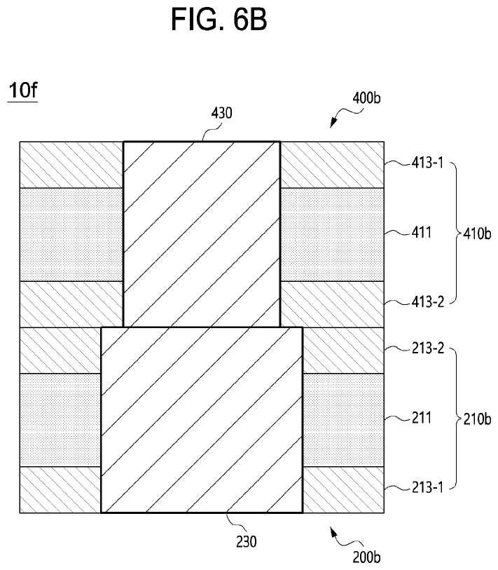

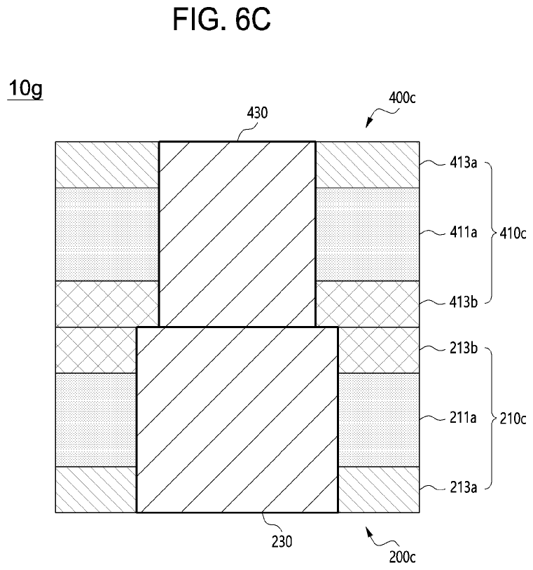

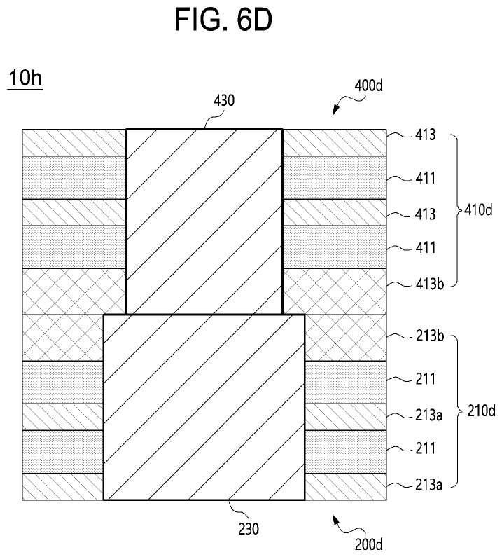

FIGS. 6A to 6D are cross-sectional views illustrating various examples of a semiconductor device including a second bonding structure and a fourth bonding structure in accordance with various embodiments.

Referring to FIGS. 6A to 6D, semiconductor devices 10e, 10f, 10g and 10h of various embodiments may include the second bonding structures 200a, 200b, 200c and 200d and fourth bonding structures 400a, 400b, 400c and 400d.

The second bonding structures 200a, 200b, 200c and 200d may include the second multi-layered dielectric layer 210a, 210b, 210c or 210d and at least one second metal pad 230 in the second multi-layered dielectric layer 210a, 210b, 210c or 210d, as mentioned above. The fourth bonding structures 400a, 400b, 400c and 400d may include a fourth multi-layered dielectric layer 410a, 410b, 410c or 410d and at least one fourth metal pad 430 in the fourth multi-layered dielectric layer 410a, 410b, 410c or 410d.

Referring to FIG. 6A, the semiconductor device 10e may include the fourth bonding structure 400a. The fourth bonding structure 400a may include at least one oxide layer 411, and at least one nitride layer 413 as a vertical expansion inducing layer. For example, the fourth bonding structure 400a may be bonded to the second bonding structure 200a including the second multi-layered dielectric layer 210a, referring to FIG. 5A.

As described above, the second multi-layered dielectric layer 210a may include the oxide layer 211 and the nitride layer 213. The fourth multi-layered dielectric layer 410a may include an oxide layer 411 and a nitride layer 413.

A volume ratio of the nitride layer 213 with respect to a total volume of the second multi-layered dielectric layer 210a may be about 40% to about 90%, particularly, about 50% to about 70%, more particularly, about 60% to about 70%. A volume ratio of the fourth nitride layer 413 with respect to a total volume of the fourth multi-layered dielectric layer 410a may be about 40% to about 90%, particularly, about 50% to about 70%, more particularly, about 60% to about 70%.

For example, the second bonding structure 200a and the fourth bonding structure 400a may have the same structure. The second bonding structure 200a and fourth bonding structure 400a may be hybrid-bonded, so that the nitride layer 213 of the second multi-layered dielectric layer 210a faces the nitride layer 413 of the fourth multi-layered dielectric layer 410a.

Referring to FIG. 6B, the second multi-layered dielectric layer 210b of the semiconductor device 10f may include a first nitride layer 213-1, an oxide layer 211 and a second nitride layer 213-2. The fourth multi-layered dielectric layer 410b may include a first nitride layer 413-1, an oxide layer 411 and a second nitride layer 413-2. A volume ratio of the first and second nitride layers 213-1 and 213-2 with respect to a total volume of the second multi-layered dielectric layer 210b may be about 40% to about 90%, particularly, about 50% to about 70%, more particularly, about 60% to about 70%. An aggregate ratio of the first and second nitride layers 413-1 and 413-2 with respect to a total volume of the fourth multi-layered dielectric layer 410b may be about 40% to about 90%, particularly, 50% to about 70%, more particularly, 60% to about 70%.

Further, a volume ratio of the second multi-layered dielectric layer 210b and the fourth multi-layered dielectric layer 410b may be about 0.5:1.5 to about 1.5:0.5 by controlling thicknesses of the silicon nitride layers 413-1 and 413-2.

Referring to FIG. 6C, the second multi-layered dielectric layer 210c may include a silicon nitride layer 213a, a silicon oxide layer 211a and a silicon carbon nitride layer 213b sequentially stacked. The fourth multi-layered dielectric layer 410c may include a silicon carbon nitride layer 413b, a silicon oxide layer 411a and a silicon nitride layer 413a sequentially stacked. For example, the fourth bonding structure 400c may be bonded to the second bonding structure 200c so that the silicon carbon nitride layer 213b of the second multi-layered dielectric layer 210c and the silicon carbon nitride layer 413b of the fourth multi-layered dielectric layer 410c are facing each other.

A volume ratio of the silicon nitride layer 213a and the silicon carbon nitride layer 213b with respect to a total volume of the second multi-layered dielectric layer 210c may be about 40% to about 90%, particularly, about 50% to about 70%, more particularly, about 50% to about 60%. A volume ratio of the silicon nitride layer 413a and the silicon carbon nitride layer 413b with respect to a total volume of the fourth multi-layered dielectric layer 410c may be about 40% to about 90%, particularly, about 50% to about 70%, more particularly, about 50% to about 60%. A volume ratio of the silicon oxide layer 211a with respect to the total volume of the second multi-layered dielectric layer 210c and A volume ratio of the silicon oxide layer 411a with respect to the total volume of the fourth multi-layered dielectric layer 410c may be about 10% to about 60%.

Referring to FIG. 6D, the second multi-layered dielectric layer 210d may include the silicon nitride layer 213a and the oxide layer 211 alternately stacked at least twice. Further, the second multi-layered dielectric layer 210d may include the silicon carbon nitride layer 213b formed on an upper surface of the second multi-layered dielectric layer 210d. The fourth multi-layered dielectric layer 410d may include the silicon nitride layer 413 and the oxide layer 411 alternately stacked at least twice. Further, the fourth multi-layered dielectric layer 410d may include the silicon carbon nitride layer 413b formed on a lower surface of the fourth multi-layered dielectric layer 410d.

A volume ratio of the silicon nitride layer 413 and the silicon carbon nitride layer 413b with respect to a total volume of the fourth multi-layered dielectric layer 410d may be about 40% to about 90%. A volume ratio of the oxide layers 411 with respect to the total volume of the fourth multi-layered dielectric layer 410d may be about 10% to about 60%.

The semiconductor devices 10e, 10f, 10g and 10h may form the bonded structure at the interfaces by the hybrid bonding process without the disconnection.

In the semiconductor devices 10a, 10b, 10c, 10d, 10e, 10f, 10g and 10h, the oxide layer may have the lowermost modulus. Thus, in an embodiment, when the metal pad is thermally expanded, the oxide layer may function as to buffer to prevent or mitigate the excessive deformation of the metal pad. The oxide layer may include the silicon oxide layer. The nitride layer may have the high strength modulus. Thus, in an embodiment, when the metal pad is thermally expanded, the nitride layer may prevent or mitigate the thermal expansion of the metal pad in the lateral direction. The nitride layer may induce the thermal expansion of the metal pad along the vertical direction. Particularly, the silicon carbon nitride layer may have a modulus between a modulus of the silicon oxide layer and a modulus of the silicon nitride layer. The silicon carbon nitride layer may have the high thermal stability, the high bonding strength and the metal expansion barrier characteristic so that the silicon carbon nitride layer may be used for a material for directly bonding the wafers to each other.

Particularly, in an embodiment, when the dielectric layers corresponding to a bonding insulation layer are bonded to each other, the vertical expansion inducing layer such as the silicon nitride layer and the silicon carbon nitride layer may induce the strong bonding by a non-metal at a temperature of below 250° C. compared when the silicon oxide layers may be bonded to each other.

Therefore, in an embodiment, in the semiconductor devices, 10a, 10b, 10c, 10d, 10e, 10f, 10g and 10h, the nitride layer may have a modulus higher than a modulus of the oxide layer to prevent or mitigate the thermal expansion of the metal pad in the lateral direction. In contrast, the nitride layer may induce the thermal expansion of the metal pad along the vertical direction in the hybrid wafer bonding process to facilitate the bonding of the metal pads. In an embodiment, the oxide layer may buffer the stresses applied to the metal pad by the annealing process to prevent or mitigate the excessive deformation of the metal pad.

Therefore, in the semiconductor devices 10a, 10b, 10c, 10d, 10e, 10f, 10g and 10h, the volume ratio of the nitride layer with respect to the total volume of the multi-layered dielectric layer in the bonding structure may be about 40% to about 90%. As a result, in an embodiment, the disconnection might not be generated at the bonding surface between the metal pads so that the semiconductor devices 10a, 10b, 10c, 10d, 10e, 10f, 10g and 10h may have improved electrical characteristics.

In FIGS. 6A to 6D, the second metal pad 230 and the fourth metal pad 430 may have the different cross-sectional shapes, but not limited thereto. The second metal pad 230 and the fourth metal pad 430 may have the same cross-sectional shape. Particularly, the different cross-sectional shapes may be provided to the second metal pad 230 and the fourth metal pad 430 to secure the bonding margin between the second metal pad 230 and the fourth metal pad 430.

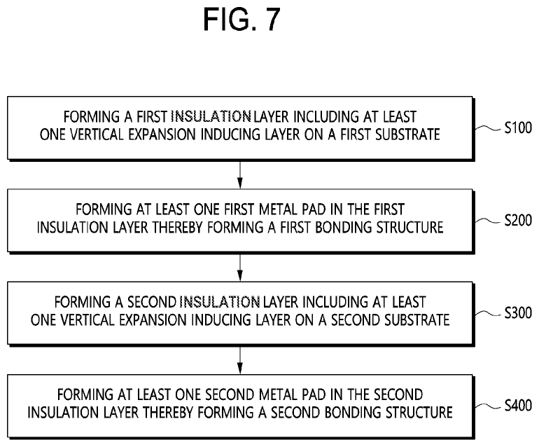

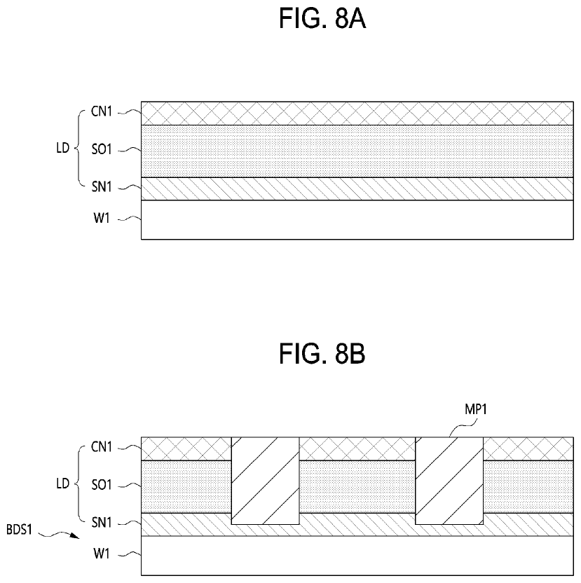

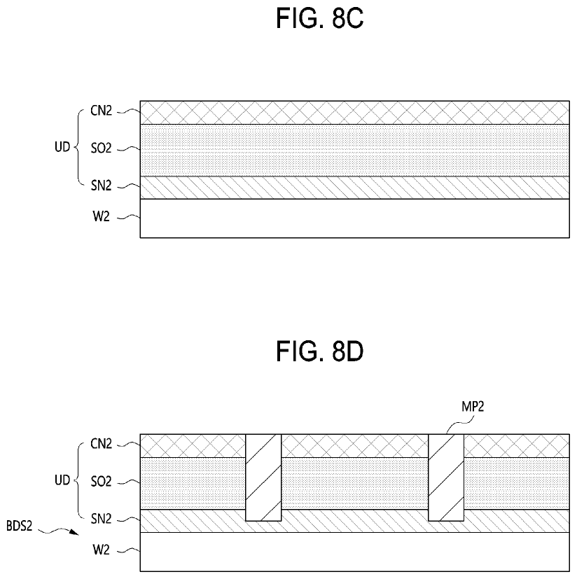

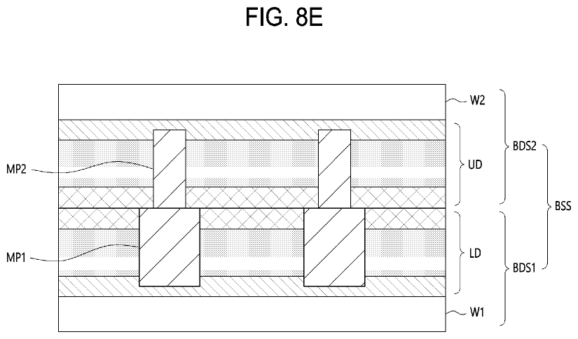

FIG. 7 is a flow chart for illustrating a method of manufacturing a semiconductor device in accordance with various embodiments. FIGS. 8A to 8E are cross-sectional views illustrating a method of manufacturing a semiconductor device in accordance with various embodiments.

Referring to FIG. 7 and FIG. 8A, in step S100, a first bonding insulation layer LD may be formed on a first substrate W1. The first bonding insulation layer LD may include at least one vertical expansion inducing layer SN1, CN1 and at least one buffer layer SO1. As mentioned above, the vertical expansion inducing layer SN1, CN1 and the buffer layer SO1 may include a dielectric material. The vertical expansion inducing layer SN1, CN1 may be denser and harder than the buffer layer SO1. For example, the vertical expansion inducing layer SN1 may be a silicon nitride layer and the vertical expansion inducing layer CN1 may be a silicon carbon nitride layer. The buffer layer SO1 may be a silicon oxide layer. The first substrate W1 may have a plurality of semiconductor circuit patterns (not shown). Alternately, the first substrate W1 may be a bare silicon substrate.

Referring to FIG. 7 and FIG. 8B, in step S200, at least one first metal pad MP1 may be formed in the first insulation layer LD. More detailed, the first insulation layer LD may be etched to form at least one first opening (not shown). A metal layer, for example, a copper (Cu) layer may be formed to fill the first opening. The metal layer may be planarized to form at least one first metal pad MP1, thereby forming a first bonding structure BDS1.

Referring to FIG. 7 and FIG. 8C, in step S300, a second bonding insulation layer UD may be formed on a second substrate W2. The second bonding insulation layer UD may include at least one vertical expansion inducing layer SN2, CN2 and at least one buffer layer SO2 as like the first bonding insulation layer LD. The second substrate W2 may have a plurality of semiconductor circuit patterns (not shown). Alternately, the second substrate W2 may be a bare silicon substrate.

Referring to FIG. 7 and FIG. 8D, in step S400, at least one second metal pad MP2 may be formed in the second bonding insulation layer UD. More detailed, the second bonding insulation layer UD may be etched to form at least one second opening (not shown). A metal layer, for example, a copper (Cu) layer may be formed to fill the second opening. The metal layer may be planarized to form at least one second metal pad MP2, thereby forming a second bonding structure BDS2.

Referring to FIG. 7 and FIG. 8E, in step S500, the second bonding structure BDS2 may be stacked on the first bonding structure BDS1 to make the first metal pad MP1 and the second metal pad MP2 faced each other. The first bonding insulation layer LD and the second insulation layer UD may be bonded by van der Waals force at the first time. And then, the first and second metal pads MP1 and MP2 may be hybrid-bonded by an annealing process, thereby forming a bonding stacking structure BSS.

In various embodiments, the first bonding structure BDS1 and the second bonding structure BDS2 may include any one of the first to fourth bonding structures 100, 200, 300 and 400. Further, the first bonding structure BDS1 and the second bonding structure BDS2 may have the same structure or different structures.

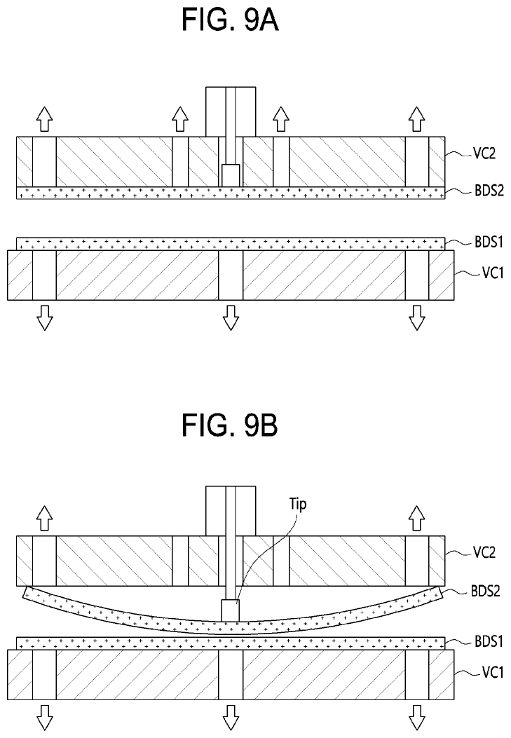

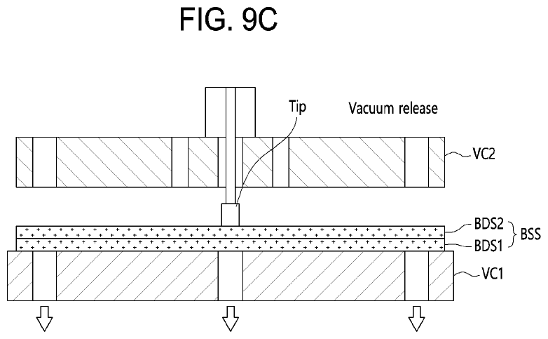

FIGS. 9A to 9C are cross-sectional views illustrating a hybrid bonding method of a lower bonding structure and an upper bonding structure according to an embodiment.

Referring to FIG. 9A, a hybrid bonding apparatus may include a lower vacuum chuck VC1 and an upper vacuum chuck VC2. In order to form the bonding stacking structure, the first bonding structure BDS1 may be loaded over the lower vacuum chuck VC1. The first bonding structure BSD1 may be fixed by vacuum. The upper vacuum chuck VC2 may pick up and fix the second bonding structure BSD2.

Referring to FIGS. 9B and 8E, the second bonding structure BDS2 may be arranged on the first bonding structure BDS1 by the upper vacuum chuck VC2. A vacuum grip in an upper inner region of the upper vacuum chuck VC2 may be released. A vacuum grip in an outer region of the upper vacuum chuck VC2 may be maintained. A center region of the second bonding structure BDS2 may touch a center region of the first bonding structure BDS1 by a stick. The vacuum grip in an upper outer region of the upper vacuum chuck VC2 may then be released to make the upper surface of the second bonding structure BDS2 contact the upper surface of the first bonding structure BSD1. The first bonding insulation layer LD of the first bonding structure BDS1 and the second bonding insulation layer UD of the second bonding structure BDS2 may be hybrid-bonded to each other. The bonding between the first and second insulation layers LD and UD may be induced by van der Waals force at a room temperature. The interface of the first metal pad MP1 might not be separated from the interface of the second metal pad MP2.

Referring to FIGS. 9C and 8E, the first and second bonding structures BSD1 and BSD2 may be annealed under about 100° C. to about 300° C. for about 1 hour to about 3 hours. Then, the metal pads MP1 and MP2 may be thermally expanded to bond the metal pads MP1 and MP2 to each other, thereby forming the bonding stacking structure BSS.

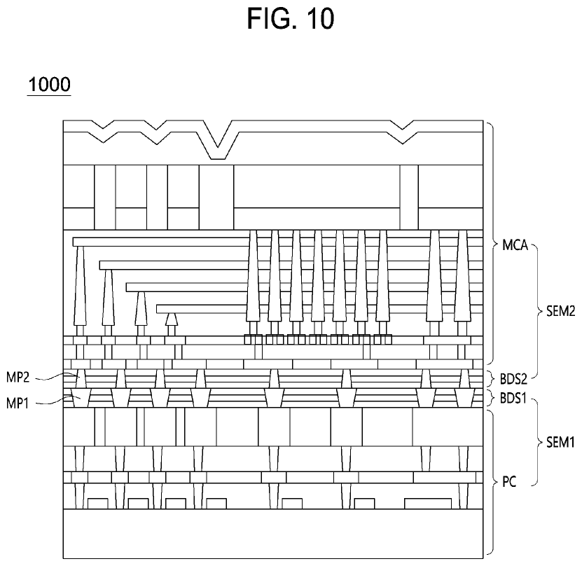

FIG. 10 is a cross-sectional view illustrating a semiconductor memory device embodied by a semiconductor device in accordance with various embodiments.

Referring to FIG. 10, a semiconductor device 1000 of various embodiments may include a first semiconductor structure SEM1 including the first bonding structure BDS1, and the second semiconductor structure SEM2 including the second bonding structure BDS2.

The first semiconductor structure SEM1 may include a plurality of peripheral circuits PC. The first bonding structure BDS1 may be formed on the plurality of peripheral circuits PC. The first metal pads MP1 of the first bonding structure BDS1 may be electrically coupled to the plurality of peripheral circuits PC, respectively. For example, the plurality of peripheral circuits PC may correspond to a device layer of the first semiconductor structure SEM1.

The second semiconductor structure SEM2 may include a memory cell array MCA. The memory cell array MCA may include a plurality of memory cells. The second bonding structure BDS2 may be formed on the memory cell array MCA. The second metal pads MP2 of the second bonding structure BDS2 may be electrically coupled to the plurality of memory cells, respectively. For example, the memory cell array MCA may correspond to a device layer of the second semiconductor structure SEM2.

The first bonding structure BDS1 of the first semiconductor structure SEM1 may be hybrid-bonded to the second bonding structure BDS2 of the second semiconductor structure SEM2. Thus, the plurality of peripheral circuits PC may be electrically coupled to the plurality of memory cells.

The above described embodiments are intended to illustrate and not to limit the description. Various alternatives and equivalents are possible. The description is not limited by the embodiments described herein. Nor are the embodiments limited to any specific type of semiconductor device.

What is claimed is:

1. A bonding structure comprising:
a plurality of bonding pads; and
a bonding insulation layer configured to electrically isolate the bonding pads from each other, the bonding insulation layer including at least one dielectric layer and at least one vertical expansion inducing layer over the dielectric layer,
wherein the vertical expansion inducing layer comprises a hardness greater than a hardness of the dielectric layer.

2. The bonding structure of claim 1, further comprising an additional vertical expansion inducing layer located under the dielectric layer.

3. The bonding structure of claim 2, wherein a total thickness of the vertical expansion inducing layer and the additional vertical expansion inducing layer corresponds to 40% to 90% of a thickness of the bonding insulation layer.

4. The bonding structure of claim 1, wherein at least one of the vertical expansion inducing layer and additional vertical expansion inducing layer comprises at least one of nitrogen and carbon.

5. The bonding structure of claim 4, wherein at least one of the vertical expansion inducing layer and additional vertical expansion inducing layer comprises at least one of a silicon nitride layer and a silicon carbon nitride layer.

6. A semiconductor device comprising:
a first bonding structure including a first bonding layer; and
a second bonding structure including a second bonding layer bonded to the first bonding layer,
wherein at least one of the first bonding layer and the second bonding layer comprises:
a plurality of bonding pads; and
a bonding insulation layer arranged between the bonding pads, the bonding insulation layer including an upper region adjacent to a bonding surface between the first and second bonding layers and a lower region under the upper region, and
wherein an interface stress between the upper region of the bonding insulation layer and the bonding pad is greater than an interface stress between the lower region of the bonding insulation layer and the bonding pad.

7. The semiconductor device of claim 6, wherein the upper region of the bonding insulation layer comprises at least one first dielectric material, the lower region of the bonding insulation layer comprises at least one second dielectric material, and the first dielectric layer comprises a hardness greater than a hardness of the second dielectric layer.

8. The semiconductor device of claim 6, wherein the bonding insulation layer further comprises a dielectric layer positioned under the lower region,
wherein the dielectric layer comprises a third dielectric material including a hardness greater than a hardness of the second dielectric material.

9. The semiconductor device of claim 8, wherein at least one of the first dielectric material and the third dielectric material comprises at least one of silicon nitride and silicon carbon nitride.

10. The semiconductor device of claim 6, wherein a thickness of the upper region of the bonding insulation layer is greater than a thickness of the lower region of the bonding insulation layer, and
wherein the upper region of the bonding insulation layer includes at least one of silicon nitride, silicon oxy-nitride, and silicon carbon nitride and the lower region of the bonding insulation layer includes silicon oxide.

11. A semiconductor device comprising:
a device layer; and
a bonding structure formed over the device layer, the bonding structure comprising a bonding insulation layer and at least one bonding pad formed in the bonding insulation layer,
wherein the bonding insulation layer includes a plurality of dielectric layers stacked from the device layer toward a bonding surface,
wherein at least one of the dielectric layers adjacent to the bonding surface comprises a first dielectric material, and remaining dielectric layers comprise a second dielectric material comprising a hardness less than a hardness of the first dielectric material.

12. The semiconductor device of claim 11, wherein a volume ratio of the first dielectric material in the bonding insulation layer is greater than a volume ratio of the second dielectric material in the bonding insulation layer.

13. The semiconductor device of claim 11, wherein a thickness of the first dielectric material is about 40% to about 90% of a thickness of the bonding insulation layer.

14. The semiconductor device of claim 11, wherein the first dielectric material comprises at least one of nitrogen and carbon.

15. A method of manufacturing a semiconductor device, the method comprising:
providing a first bonding structure including a first bonding insulation layer and at least one first bonding pad in the first bonding insulation layer;
providing a second bonding structure including a second bonding insulation layer and at least one second bonding pads in the second bonding insulation layer;
bonding the first bonding structure and the second bonding structure to make the first bonding insulation layer contact the second bonding insulation layer; and
thermally expanding the first bonding pads and the second bonding pads in a vertical direction to hybrid-bond the first bonding pads to the second bonding pads,
wherein providing the first bonding structure includes:
forming at least one first buffer layer;
forming at least one first vertical expansion inducing layer over the first buffer layer, the first vertical expansion inducing layer including a hardness higher than a hardness of the first buffer layer; and
forming the first bonding pads through the first vertical expansion inducing layer and the first buffer layer.

16. The method of claim 15, wherein the first vertical expansion inducing layer is positioned to contact the second bonding structure.

17. The method of claim 15, wherein providing the second bonding structure includes:
forming at least one second buffer layer;
forming at least one second vertical expansion inducing layer over the second buffer layer, the second vertical expansion inducing layer including a hardness higher than a hardness of the second buffer layer; and
forming the second bonding pads through the second vertical expansion inducing layer and the second buffer layer, wherein the second vertical expansion inducing layer is directly contacted the first vertical expansion inducing layer when the first bonding structure is hybrid-bonded to the second bonding structure.

18. The method of claim 16, wherein at least one of the first and second vertical expansion inducing layer comprises at least one nitrogen and carbon.

19. The method of claim 18, wherein the first vertical expansion inducing layer is formed to have a first thickness corresponding to about 40% to about 90% of a thickness of the first bonding insulation layer, and
wherein the second vertical expansion inducing layer is formed to have a thickness corresponding to about 40% to about 90% of a thickness of the second bonding insulation layer.
